(19) United States
(12) Patent Application Publication
(10) Pub. No.: US 2007/0047437 A1
(43) Pub. Date: Mar. 1, 2007

(54) Method and apparatus for controlling retransmissions in a wireless communications system

(76) Inventors: Rainer Bachl, Nuernberg Barvaria (DE); Francis Dominique, Whippany, NJ (US); Hongwei Kong, Whippany, NJ (US); Walid Nabhane, Bedminster, NJ (US)

Correspondence Address: WILLIAMS, MORGAN & AMERSON, 10333 RICHMOND, SUITE 1100, HOUSTON, TX, 77042, US

(21) Appl. No.: 11/211,165

(22) Filed: Aug. 24, 2005

(51) Int. Cl. H04L 12/26; H04L 1/00; H03M 13/00; H04L 12/66; G01R 31/08

(52) U.S. Cl. 370/229; 370/352; 714/746

(57) ABSTRACT

A method is provided for controlling communications between a base station and a mobile device when transmission gaps occur. The method comprises skipping a transmission that overlaps with the transmission gap. An alternative method comprises postponing the transmission to the next available transmission time.

### BACKGROUND OF THE INVENTION

1. Field of the Invention

This invention relates generally to telecommunications, and, more particularly, to wireless communications.

2. Description of the Related Art

In the field of wireless telecommunications, such as cellular telephony, a system typically includes a plurality of base stations (or NodeBs in 3GPP (3^{rd} Generation Partnership Project) terminology) distributed within an area to be serviced by the system. Various mobile devices (or User Equipment-UE in 3GPP terminology) within the area may then access the system and, thus, other interconnected telecommunications systems, via one or more of the base stations. Typically, a mobile device maintains communications with the system as it passes through an area by communicating with one or more base stations, as the mobile device moves. The process of moving among base stations is commonly referred to as a soft handoff and it may occur relatively often if the mobile device is moving rapidly. The mobile device may communicate with the closest base station, the base station with the strongest signal, the base station with a capacity sufficient to accept communications, etc.

To allow a mobile device to periodically communicate with these other base stations, a wireless system, such as UMTS (Universal Mobile Telecommunications System), allows gaps to periodically occur where the mobile device is not required to communicate with its current serving base station, but may instead use the gap to monitor other base stations to which it may subsequently desire to handoff. Typically, for a small transmission time interval, such as 2 ms (millisecond). data packets in 3GPP-UMTS, when a transmission overlaps with the transmission gap, the entire transmission for that 2 ms period is cancelled regardless how much the overlap is. However, this canceling of a transmission can create some difficulties in wireless systems, such as 3GPP systems, that support automatic retransmissions (e.g., Hybrid Automatic Repeat Requests (HARQs)) so that the base station can combine initial transmission and successive following retransmissions correctly. For example, successive retransmissions are indicated by retransmission sequence numbers, as the actual data transmitted on each retransmission may be different from each other as well as from the initial transmission even though they come from the same data packet (e.g., the actual data transmitted can be a different part of the data packet for each retransmission). If the initial (first) transmission or any following retransmission is cancelled, and the mobile device does not “know” which retransmission sequence number will be subsequently sent as the retransmission, and the base station may confuse the type of retransmission and erroneously accept or discard the received data.

### SUMMARY OF THE INVENTION

The present invention is directed to overcoming, or at least reducing, the effects of one or more of the problems set forth above. The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

In one aspect of the instant invention, a method is provided for controlling communications in a wireless communications system. The method comprises receiving an indication of a transmission gap. A first retransmission is then cancelled in response to the first retransmission being scheduled to overlap with the transmission gap. A second retransmission is then scheduled having a retransmission sequence number selected based upon the first retransmission being cancelled.

In another aspect of the instant invention, a method is provided for sequence transmission. The method comprises determining if a transmission overlaps with a transmission gap. The transmission is cancelled in response to determining that transmission overlaps with the transmission gap. The transmission and a corresponding retransmission sequence number associated therewith are then postponed to a later transmission time.

In yet another aspect of the instant invention, a method is provided for sequence transmission. The method comprises determining if a transmission of a data packet overlaps with a transmission gap. The transmission is cancelled if it overlaps with the transmission gap. The transmission and a corresponding retransmission sequence number are then postponed to a later transmission time in response to the transmission of the data packet being a first attempt to transmit the data packet. The transmission and a corresponding retransmission sequence number are skipped in response to the transmission of the data packet not being the first attempt to transmit the data packet.

### BRIEF DESCRIPTION OF THE DRAWINGS

The invention may be understood by reference to the following description taken in conjunction with the accompanying drawings, in which like reference numerals identify like elements, and in which:

FIG. 1 is a block diagram of a communications system, in accordance with one embodiment of the present invention; and

FIG. 2 depicts a block diagram of one embodiment of a base station and a mobile device in the communications system of FIG. 1;

FIGS. 3A and 3B depict a timing diagram of one embodiment of a method that may be used to control retransmissions by the mobile devices of FIGS. 1 and 2;

FIG. 4 illustrates a flowchart depicting operation of one embodiment of a mobile device in the communications system of FIG. 1;

FIGS. 5A and 5B depict a timing diagram of an alternative embodiment of a method that may be used to control retransmissions by the mobile devices of FIGS. 1 and 2; and

FIG. 6 illustrates a flowchart depicting operation of one embodiment of a mobile device in the communications system of FIG. 1.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF SPECIFIC EMBODIMENTS

Illustrative embodiments of the invention are described below. In the interest of clarity, not all features of an actual implementation are described in this specification. It will of course be appreciated that in the development of any such actual embodiment, numerous implementation-specific decisions may be made to achieve the developers' specific goals, such as compliance with system-related and business-related constraints, which may vary from one implementation to another. Moreover, it will be appreciated that such a development effort might be complex and time-consuming, but may nevertheless be a routine undertaking for those of ordinary skill in the art having the benefit of this disclosure.

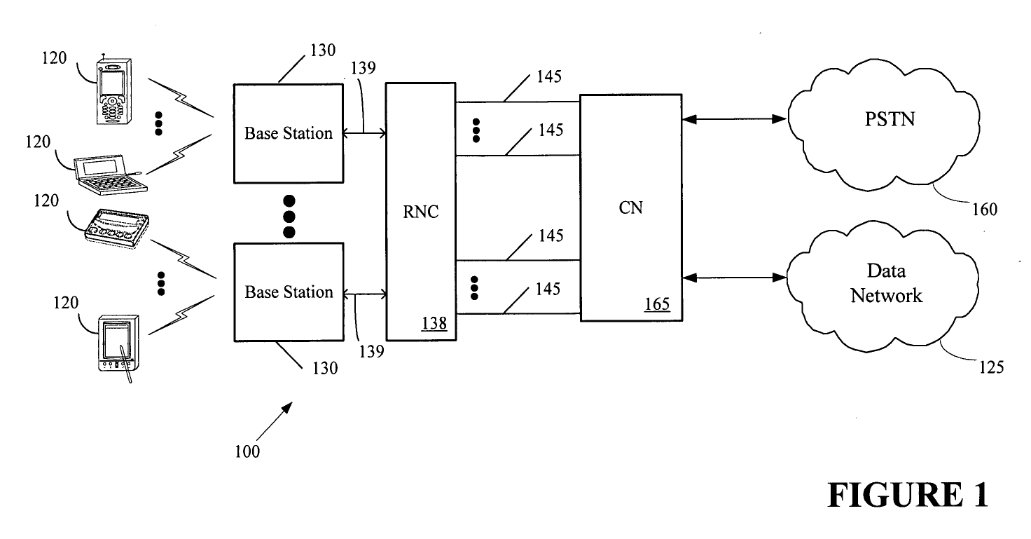

Turning now to the drawings, and specifically referring to FIG. 1, a communications system 100 is illustrated, in accordance with one embodiment of the present invention. For illustrative purposes, the communications system 100 of FIG. 1 is generally compliant with technical specifications and technical reports for a 3^{rd} Generation Mobile System that have been developed by the 3^{rd} Generation Partnership Project (3GPP). Although it should be understood that the present invention may be applicable to other systems that support data and/or voice communications. The communications system 100 allows one or more mobile devices 120 to communicate with a data network 125, such as the Internet, and/or a Publicly Switched Telephone Network (PSTN) 160 through one or more base stations 130. The mobile device 120 may take the form of any of a variety of devices, including cellular phones, personal digital assistants (PDAs), laptop computers, digital pagers, wireless cards, and any other device capable of accessing the data network 125 and/or the PSTN 160 through the base station 130.

In one embodiment, a plurality of the base stations 130 may be coupled to a Radio Network Controller (RNC) 138 by one or more connections 139, such as T1/EI lines or circuits, ATM circuits, cables, optical digital subscriber lines (DSLs), and the like. Although one RNC 138 is illustrated, those skilled in the art will appreciate that a plurality of RNCs 138 may be utilized to interface with a large number of base stations 130. Generally, the RNC 138 operates to control and coordinate the base stations 130 to which it is connected. The RNC 138 of FIG. 1 generally provides replication, communications, runtime, and system management services. The RNC 138, in the illustrated embodiment handles calling processing functions, such as setting and terminating a call path and is capable of determining a data transmission rate on the forward and/or reverse link for each user 120 and for each sector supported by each of the base stations 130.

The RNC 138 is also coupled to a Core Network (CN) 165 via a connection 145, which may take on any of a variety of forms, such as T1/EI lines or circuits, ATM circuits, cables, optical digital subscriber lines (DSLs), and the like. Generally the CN 165 operates as an interface to a data network 125 and/or to the PSTN 160. The CN 165 performs a variety of functions and operations, such as user authentication, however, a detailed description of the structure and operation of the CN 165 is not necessary to an understanding and appreciation of the instant invention. Accordingly, to avoid unnecessarily obfuscating the instant invention, further details of the CN 165 are not presented herein.

The data network 125 may be a packet-switched data network, such as a data network according to the Internet Protocol (IP). One version of IP is described in Request for Comments (RFC) 791, entitled “Internet Protocol,” dated September 1981. Other versions of IP, such as IPv6, or other connectionless, packet-switched standards may also be utilized in further embodiments. A version of IPv6 is described in RFC 2460, entitled “Internet Protocol, Version 6 (IPv6) Specification,” dated December 1998. The data network 125 may also include other types of packet-based data networks in further embodiments. Examples of such other packet-based data networks include Asynchronous Transfer Mode (ATM), Frame Relay networks, and the like.

As utilized herein, a “data network” may refer to one or more communication networks, channels, links, or paths, and systems or devices (such as routers) used to route data over such networks, channels, links, or paths.

Thus, those skilled in the art will appreciate that the communications system 100 facilitates communications between the mobile devices 120 and the data network 125 and/or the PSTN 160. It should be understood, however, that the configuration of the communications system 100 of FIG. 1 is exemplary in nature, and that fewer or additional components may be employed in other embodiments of the communications system 100 without departing from the spirit and scope of the instant invention.

Unless specifically stated otherwise, or as is apparent from the discussion, terms such as “processing” or “computing” or “calculating” or “determining” or “displaying” or the like, refer to the action and processes of a computer system, or similar electronic computing device, that manipulates and transforms data represented as physical, electronic quantities within the computer system's registers and memories into other data similarly represented as physical quantities within the computer system's memories or registers or other such information storage, transmission or display devices.

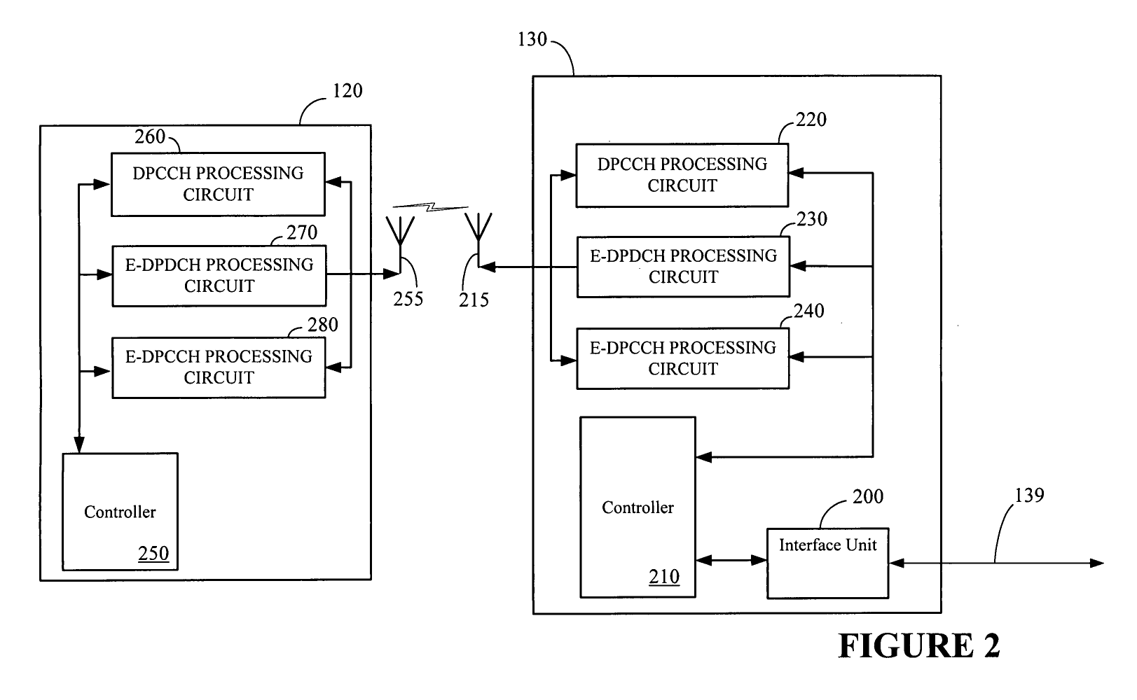

Referring now to FIG. 2, a block diagram of one embodiment of a functional structure associated with an exemplary base station 130 and mobile device 120 is shown for communications between the base station 130 and the mobile device 120, using the Enhanced Dedicated CHannel (E-DCH), where HARQ is used for data transmission. The base station 130 includes an interface unit 200, a controller 210, an antenna 215 and a plurality of channels, such as a DPCCH (Dedicated Physical Control CHannel), an E-DPDCH (E-DCH Dedicated Physical CHannel) and an E-DPCCH (E-DCH Dedicated Physical Control CHannel) along with processing circuitry 220, 230, 240 associated with each of these channels. Those skilled in the art will appreciate that the processing circuitry 220, 230, 240 may be comprised of hardware, software or a combination thereof.

The interface unit 200, in the illustrated embodiment, controls the flow of information between the base station 130 and the RNC 138 (see FIG. 1). The controller 210 generally operates to control both the transmission and reception of data and control signals over the antenna 215 and the plurality of channels between the base station 130 and the mobile device 120, and to communicate at least portions of the received information to the RNC 138 via the interface unit 200. The DPCCH processing circuit 220 extracts information sent by the UE 120 over the DPCCH channel, and uses it to do tasks such as channel estimation, synchronization, channel monitoring, etc. The E-DPCCH processing circuit 240 extracts information sent by the mobile device 120 over the E-DPCCH channel. Typically, the E-DPCCH channel carries control information about the E-DPDCH channel, such as the block size, retransmission sequence number, etc. The information is used by the E-DPDCH processing circuit 230 to process the data sent by the mobile device 120 over E-DPDCH. The E-DPDCH processing circuit 230 may include removing channel impairment using the channel estimate from DPCCH processing circuit 220, combining transmission and successive retransmissions using the retransmission sequence number from E-DPCCH processing circuit 240 and then decoding to recover the data packet.

The mobile device 120 shares certain functional attributes with the base station 130. For example, the mobile device 120 includes a controller 250, an antenna 255 and a plurality of channels and processing circuitry, such as a DPCCH processing circuit 260, a E-DPDCH processing circuit 270, a E-DPCCH processing circuit 280, and the like. The controller 250 generally operates to control both the transmission and reception of data and control signals over the antenna 255 and the plurality of channels 260, 270, 280.

Normally, the channels in the mobile device 120 communicate with the corresponding channels in the base station 130. Under the operation of the controllers 210, 250, the channels and their associated processing circuits 220, 260; 230, 270; 240, 280 are used to effect a controlled scheduling for communications between the mobile device 120 and the base station 130.

Typically, operation of the channels and their associated processing circuits 260, 270, 280 in the mobile device 120 and the corresponding channels and processing circuits 220, 230, 240 in the base station 130 have been subframe (2 ms) or frame (10 ms) operated. For example, in each subframe, control information meant for E-DPDCH in the mobile device 120 connected to the base station 130 is transmitted, in addition to at least portion of the user data E-DPDCH for mobile devices 120 transmitted at the same subframe. Typically, the control information may include information regarding the retransmission sequence numbering and rate (or block size) at which the mobile devices 120 are transmitting.

Periodically, the mobile devices 120 are permitted to monitor with other base stations 130 in the immediate area. In this way, the mobile devices 120 may periodically determine the quality of communications that would be available with an alternative serving base station. Ultimately, the mobile devices 120 may “decide” to move to a different serving base station 130 based on various measured criteria. At that time, the mobile device 120 will enter a soft handoff mode and the process will be implemented through the coordinated efforts of the current serving base station 130, the target base station 130 and the mobile device 120.

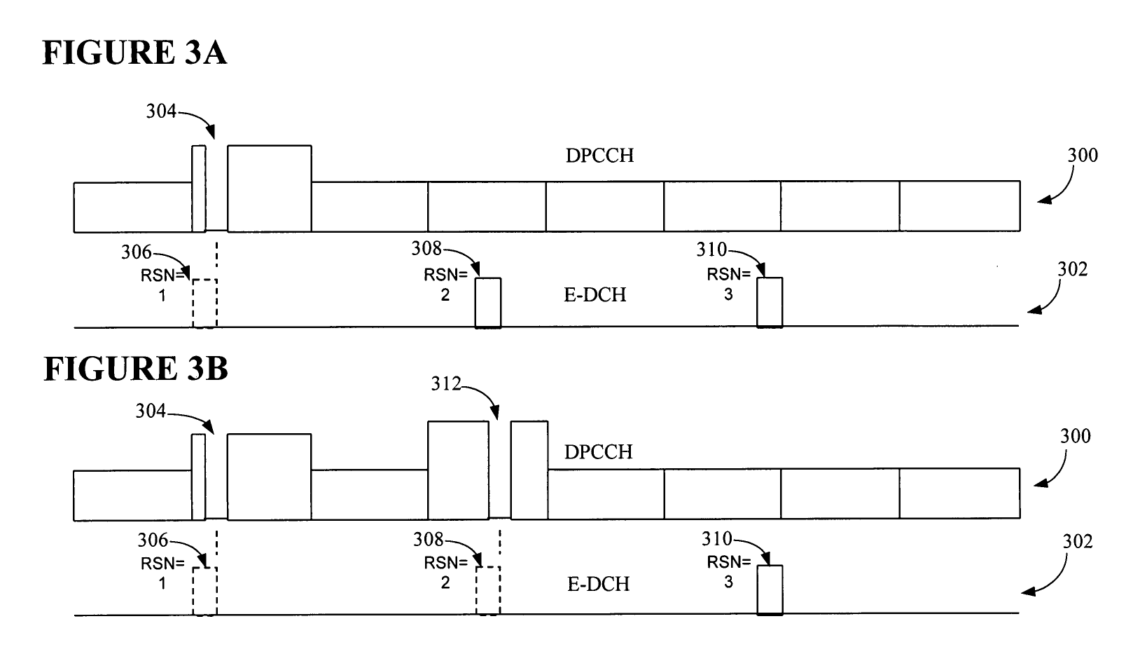

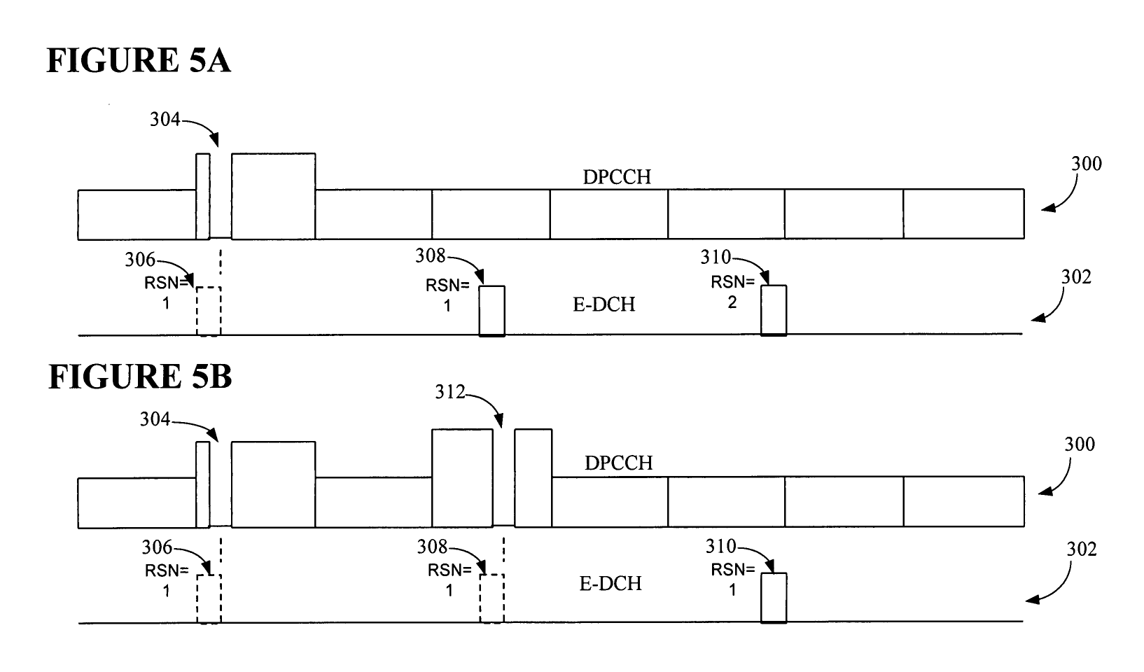

During these periods of time when the mobile devices 120 are permitted to monitor other base stations 130, the mobile device 120 interrupts its communication with the serving base station 130. This is achieved by canceling all transmissions for a certain amount of time to the serving base station 130, as illustrated in FIG. 3 and FIG. 5. The cancelled period of time is usually referred to as the “transmission gap.” For E-DCH with short data frames (e.g., 2 msec.), when a transmission overlaps with a transmission gap, the transmission is cancelled. For mobile devices 120 and base stations 130 to work correctly together, there may be a need in some embodiments to specify how the retransmissions are handled, otherwise the base station 130 will not “know” when and how to properly combine the initial transmission with successive retransmissions for the same packet. In one embodiment of the instant invention, the manner in which the retransmission number is transmitted over the control channel E-DPCCH is specified.

For example, turning to FIG. 3A, a timing diagram illustrating a method that may be employed by the mobile device 120 to control retransmissions is shown. FIG. 3A illustrates two channel types over which the mobile device 120 may communicate with the serving base station 130, an uplink data channel and an uplink control channel. In one embodiment of the instant invention, the uplink control channel takes the form of a Dedicated Physical Control Channel (DPCCH) 300, and the uplink data channel takes the form of an Enhanced Dedicated Channel (EDCH) 302, which may be comprised of both a data and control channel, such as an Enhanced Dedicated Physical Data Channel (E-DPDCH) and an Enhanced Dedicated Physical Control Channel (E-DPCCH).

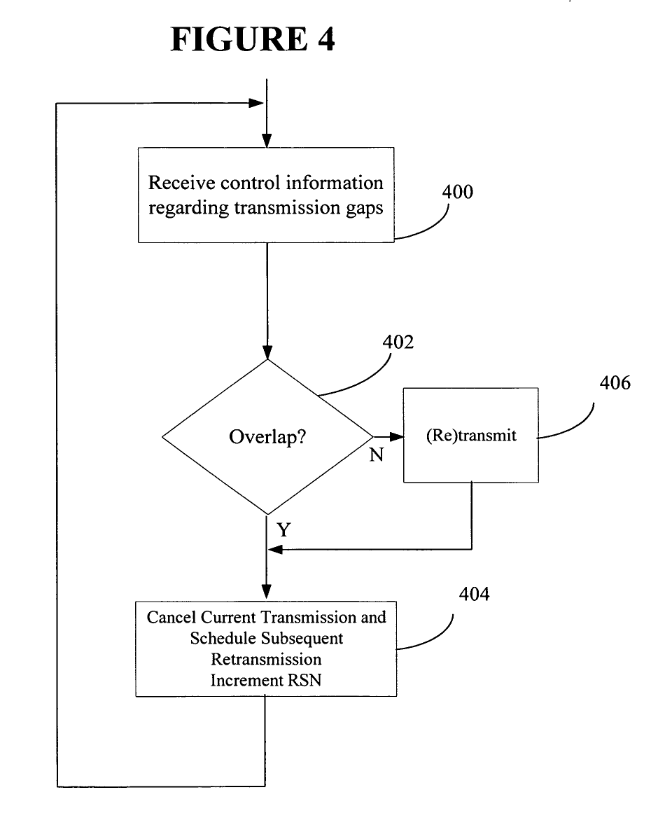

Operation of the instant invention may be appreciated by simultaneous reference to the timing diagrams of FIGS. 3A and 3B and a flow chart of FIG. 4 during the following discussion. The process begins at block 400 with the mobile device 120 receiving control information from RNC 138 regarding the transmission gap patterns. In particular, the RNC 138 indicates that a transmission gap 304 is scheduled to occur at a particular time. By way of example, the mobile device 120 has attempted an original transmission (not shown), which was unsuccessful. The base station 130 delivered a Negative Acknowledgement (NACK) to the mobile device, indicating that the transmission was not properly received. The mobile device 120 responded to the NACK by scheduling a first retransmission 306, which in the exemplary embodiment is a first type of retransmission, as indicated by a Retransmission Sequence Number (RSN). In particular, the mobile device 120 sets RSN=1. However, in the exemplary timing diagram of FIG. 3A, the retransmission 306 overlaps with the transmission gap 304. Accordingly, at block 402, the mobile device 120 identifies the overlap between the retransmission 306 and the transmission gap 304. At block 404, the mobile device 120 cancels the retransmission 306 and does not deliver the retransmission 306 to the base station 130.

Thereafter, at block 404, the mobile device 120 schedules a second retransmission 308. In one embodiment of the instant invention, even though the first retransmission was not sent, the mobile device 120 still increments the RSN and schedules the second retransmission to be a second type of retransmission. In particular, the mobile device 120 sets RSN=2. Since no transmission gap is scheduled to overlap with the retransmission 308 in the exemplary embodiment of FIG. 3A, control transfers to block 406 where the mobile device 120 delivers the retransmission 308 over EDCH at the scheduled time.

If the retransmission 308 is unsuccessful, as indicated by the mobile device 120 receiving a NACK from the base station 130, then the mobile device 120 schedules a third retransmission 310 at block 404. In one embodiment of the instant invention, the mobile device 120 increments the RSN and schedules the third retransmission 310 to be a third type of retransmission. In particular, the mobile device 120 sets RSN=3 at block 404. Since no transmission gap is scheduled to overlap with the retransmission 310 in the exemplary embodiment of FIG. 3A, the mobile device 120 at block 406 delivers the retransmission 310 over EDCH at the scheduled time.

FIG. 3B illustrates a scenario in which multiple retransmissions 306, 308 overlap with multiple transmission gaps 304, 312. For example, in the illustrated scenario, both the first retransmission 306 and the second retransmission 308 are shown to overlap with transmission gaps 304, 312 respectively. Accordingly, both the first retransmission 306 and the second retransmission 308 are cancelled and not sent. The RSN, however, is incremented even though neither of the retransmissions 306, 308 is sent. In one embodiment of the instant invention, the mobile device 120 increments the RSN and schedules the third retransmission 310 to be a third type of retransmission. In particular, the mobile device 120 sets RSN=3. Since no transmission gap is scheduled to overlap with the retransmission 310 in the exemplary embodiment of FIG. 3B, the mobile device 120 delivers the retransmission 310 over EDCH at the scheduled time.

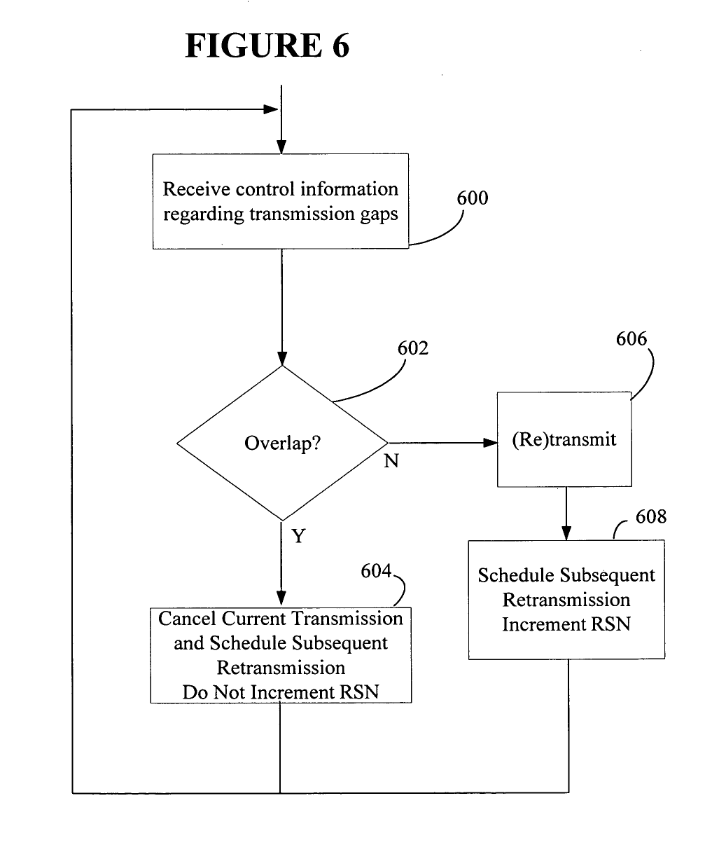

Turning now to FIGS. 5A and 6, the operation of an alternative embodiment of the instant invention is shown. In this embodiment of the instant invention, the RSN is only incremented if the previous retransmission was sent. For example, the process begins at block 600 with mobile device 120 receiving control information from the RNC 138. In particular, the RNC 138 indicates that a transmission gap 304 is scheduled to occur at a particular time. By way of example, the mobile device 120 has attempted an original transmission (not shown), which was unsuccessful. The base station 130 delivered a Negative Acknowledgement (NACK) to the mobile device, indicating that the transmission was not properly received. The mobile device 120 responded to the NACK by scheduling a first retransmission 306, which in the exemplary embodiment is a first type of retransmission, as indicated by a Retransmission Sequence Number (RSN). In particular, the mobile device 120 sets RSN=1. However, in the exemplary timing diagram of FIG. 5A, the retransmission 306 overlaps with the transmission gap 304. Accordingly, at block 602, the mobile device 120 identifies the overlap and cancels the retransmission 306.

Thereafter, at block 604 the mobile device 120 schedules a second retransmission 308. In one embodiment of the instant invention, because the first retransmission 306 was not sent, the mobile device 120 does not increment the RSN and schedules the second retransmission to be a first type of retransmission. In particular, the mobile device 120 sets RSN=1. Since no transmission gap is scheduled to overlap with the second retransmission 308 in the exemplary embodiment of FIG. 5A, the mobile device 120 at block 606 delivers the retransmission 308 over EDCH at the scheduled time.

If the retransmission 308 is unsuccessful, as indicated by the mobile device 120 receiving a NACK from the base station 130, then the mobile device 120 at block 608 schedules a third retransmission 310. In one embodiment of the instant invention, because the second retransmission 308 was actually sent, the mobile device 120 increments the RSN and schedules the third retransmission 310 to be a second type of retransmission. In particular, the mobile device 120 sets RSN=2. Since no transmission gap is scheduled to overlap with the retransmission 310 in the exemplary embodiment of FIG. 5A, the mobile device 120 at block 606 delivers the retransmission 310 over EDCH at the scheduled time.

FIG. 5B illustrates a scenario in which multiple retransmissions 306, 308 overlap with multiple transmission gaps 304, 312. For example, in the illustrated scenario, both the first retransmission 306 and the second retransmission 308 are shown to overlap with transmission gaps 304, 312 respectively. Accordingly, both the first retransmission 306 and the second retransmission 308 are cancelled and not sent. Thus the RSN is not incremented because neither of the retransmissions 306, 308 was sent. In one embodiment of the instant invention, the mobile device 120 does not increment the RSN and schedules the third retransmission 310 to be the first type of retransmission. In particular, the mobile device 120 sets RSN=1. Since no transmission gap is scheduled to overlap with the retransmission 310 in the exemplary embodiment of FIG. 5B, the mobile device 120 delivers the retransmission 310 over EDCH at the scheduled time.

In an alternative embodiment of the instant invention, it may be useful to combine the two approaches discussed above to ensure the initial transmission (with RSN=0) is always transmitted. This is because UMTS requires that the first transmission is self-decodable so its reception is very much desired. In this combined approach, if the first transmission with RSN=0 overlaps with the transmission gap, then it is postponed to the next available transmission time. If later retransmissions, if any, overlap with transmission gaps, those retransmissions are then skipped and the RSN is incremented as if there is no transmission gap.

Those skilled in the art will appreciate that the various system layers, routines, or modules illustrated in the various embodiments herein may be executable control units. The control units may include a microprocessor, a microcontroller, a digital signal processor, a processor card (including one or more microprocessors or controllers), a FPGA, a ASIC (Application Specific Integrated Circuits), a ASSP (Application Specific Standard Product) or other control or computing devices. The storage devices referred to in this discussion may include one or more machine-readable storage media for storing data and instructions. The storage media may include different forms of memory including semiconductor memory devices such as dynamic or static random access memories (DRAMs or SRAMs), erasable and programmable read-only memories (EPROMs), electrically erasable and programmable read-only memories (EEPROMs) and flash memories; magnetic disks such as fixed, floppy, removable disks; other magnetic media including tape; and optical media such as compact disks (CDs) or digital video disks (DVDs). Instructions that make up the various software layers, routines, or modules in the various systems may be stored in respective storage devices. The instructions when executed by the control units cause the corresponding system to perform programmed acts.

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. Consequently, the method, system and portions thereof and of the described method and system may be implemented in different locations, such as the wireless unit, the base station, a base station controller and/or mobile switching center. Moreover, processing circuitry required to implement and use the described system may be implemented in application specific integrated circuits, software-driven processing circuitry, firmware, programmable logic devices, hardware, discrete components or arrangements of the above components as would be understood by one of ordinary skill in the art with the benefit of this disclosure. It is therefore evident that the particular embodiments disclosed above may be altered or modified and all such variations are considered within the scope and spirit of the invention. Accordingly, the protection sought herein is as set forth in the claims below.

We claim:

1. A method for controlling retransmissions in a wireless communications system, comprising:
receiving an indication of a transmission gap;
canceling a first retransmission scheduled to overlap with the transmission gap; and
scheduling a second retransmission having a retransmission sequence number selected based upon the first retransmission being cancelled.

2. A method, as set forth in claim 1, wherein scheduling the second retransmission having the retransmission sequence number selected based upon the first retransmission being cancelled further comprising using the same retransmission sequence number for both the first and second retransmissions in response to the first retransmission being cancelled.

3. A method, as set forth in claim 1, wherein scheduling the second retransmission having the retransmission sequence number selected based upon the first retransmission being cancelled further comprising incrementing a retransmission sequence number assigned to the first retransmission to select the retransmission sequence number for the second retransmission regardless of the first retransmission being cancelled.

4. The method of claim 1, wherein scheduling a second retransmission further comprises using HARQ protocol.

5. A method, as set forth in claim 1, wherein scheduling the second retransmission further comprises scheduling the second retransmission over at least one of a DPCCH, E-DPCCH and E-DPDCH.

6. A method, as set forth in claim 5, further comprising attempting to transmit data over the E-DPDCH, and wherein the first retransmission is comprised of at least portion of the transmit data.

7. A method, as set forth in claim 6, wherein the second retransmission is comprised of at least portion of the transmit data.

8. A method, as set forth in claim 7, wherein the first and second retransmissions are differentiated by a retransmission sequence number transmitted over the E-DPDCH.

9. A method of sequence transmission, comprising:
determining if a transmission overlaps with a transmission gap;
canceling the transmission in response to determining that transmission overlaps with the transmission gap; and
postponing the transmission and a corresponding retransmission sequence number associated therewith to a later transmission time.

10. A method, as set forth in claim 9, wherein communications regarding the transmission and retransmission are performed using a HARQ protocol.

11. A method, as set forth in claim 9, wherein the transmission is to occur over at least one of a DPCCH, E-DPCCH and E-DPDCH.

12. A method, as set forth in claim 11, wherein postponing the transmission and a corresponding retransmission sequence number associated therewith to a later transmission time further comprises retransmitting data over E-DPDCH and wherein the retransmitted data is comprised of at least portion of data to have been transmitted in the cancelled transmission.

13. A method of sequence transmission, comprising:
determining if a transmission of a data packet overlaps with a transmission gap;
canceling the transmission if it overlaps with the transmission gap;
postponing the transmission and a corresponding retransmission sequence number to a later transmission time in response to the transmission of the data packet being a first attempt to transmit the data packet; and
skipping the transmission and a corresponding retransmission sequence number in response to the transmission of the data packet not being the first attempt to transmit the data packet.

14. A method, as set forth in claim 13, wherein communications regarding the transmission are performed using a HARQ protocol.

15. A method, as set forth in claim 13, wherein the transmission is to occur over at least one of a DPCCH, E-DPCCH and E-DPDCH.

16. A method, as set forth in claim 15, wherein the transmission over E-DPDCH further comprises retransmitting data and wherein the retransmitted data is comprised of at least portion of data to have been transmitted in the cancelled transmission.

17. A method, as set forth in claim 16, wherein retransmitting data further comprises retransmitting data a plurality of times wherein each retransmission of data over E-DPDCH is differentiated by a retransmission sequence number transmitted over the E-DPDCH.

18. An apparatus comprising:
means for detecting if a transmission overlaps with a transmission gap; and
means for canceling the transmission in response to determining that the transmission overlaps the transmission gap.

19. An apparatus, as set forth in claim 18, wherein the canceling means further comprises canceling a transmission over an E-DPDCH and E-DPCCH in response to determining that the transmission overlaps the transmission gap.

20. An apparatus, as set forth in claim 18, further comprising:
means for scheduling a retransmission having a retransmission sequence number selected based upon the transmission being cancelled.
